(19) United States
(12) Patent Application Publication
(10) Pub. No.: US 2025/0128912 A1
(43) Pub. Date: Apr. 24, 2025

(54) STRUCTURE AND METHOD FOR FAILURE DIAGNOSIS OF PCB BOARD FOR ARTICLE TRANSPORT ELEVATOR

(71) Applicant: Dongsub KIM, Incheon (KR)

(72) Inventor: Dongsub KIM, Incheon (KR)

(21) Appl. No.: 18/914,518

(22) Filed: Oct. 14, 2024

(30) Foreign Application Priority Data
Oct. 18, 2023 (KR) 10-2023-0139630

(51) Int. Cl. B66B 5/00; G01R 31/28; H05K 1/18

(52) U.S. Cl. CPC B66B 5/0025; B66B 5/0087; G01R 31/2815; H05K 1/181; H05K 2201/10053; H05K 2201/10113

(57) ABSTRACT

The present invention relates to a structure and method for failure diagnosis of a PCB board for article transport elevator installed and used in a multi-layer structural restaurant, factories or other business establishments. More particularly, the article transport elevator is configured such that circuit units of the PCB board are connected with lamps that turn on in accordance with whether each functional part is operated normally or not, thereby looking at the PCB board and collectively diagnosing the presence or absence of a failure of the power supply unit, the seesaw switch unit of each layer, the car arrival limit unit, the car operation condition unit and the car operation state unit in accordance with the turn-on/off operation of each lamp in a simple and quick manner, especially easily and quickly diagnosing the failure even by beginners, finally excellently providing convenience in failure diagnosis.

### CROSS-REFERENCE TO RELATED APPLICATION(S)

This application claims priority to and benefit of Korean Patent Application No. 10-2023-0139630 filed Oct. 18, 2023, the disclosure of which is incorporated herein by reference in its entirety.

### TECHNICAL FIELD

The present invention relates to a PCB board for article transport elevator installed and used in multi-layer structural restaurants factories other business establishments, and more particularly, to a structure and method for failure diagnosis of a PCB board for article transport elevator which can look at the PCB board connected to each functional unit of an elevator and diagnose the presence or absence of a failure of respective functional units.

### BACKGROUND ART

Generally, an article transport elevator is installed and used in multi-layer structural restaurants, factories, and other business establishments to easily transport various articles between layers.

Such article transport elevators ascend and descend a transport car loaded carrying articles to a locker location selected from among the lockers provided on each layer of a multi-layer structure, and supplies the articles by the door opening and closing operation of the locker where the transport car has arrived.

A conventional article transport elevator comprises various functional units such as: a power supply unit that turns the power on and off for stable operation, a seesaw switch of each layer, a car arrival limit unit that checks whether a transport car has arrived at the locker of each layer, an emergency limit unit that detects so as to prevent the transport car to coming off from the upper and lower layers, a door limit unit that checks the door opening/closing, and an ascent/descent arrow installed on each layer for the ascending/descending operation of the transport car, wherein these various functional parts are connected to the circuit unit of the PCB board so as to control them, and the PCB board is installed inside the switch board for management.

However, the above-mentioned conventional article transport elevator requires management work to diagnose and maintain each functional unit at failure, and since an operator must inspect and diagnose the normal operation of the switch board and each functional unit one by one while visiting the installed positions of the switch board and each functional unit. Therefore, there are problems in that not only the diagnosis require expertise, but a lot of time is required for diagnose and maintenance thereof, which results in a reduction in management efficiency.

### PRIOR ART LITERATURE

### Patent Literature

(Patent Literature 0001) Korean Unexamined Patent Publication No. 10-2009-0084079 (published on Aug. 5, 2009)
(Patent Literature 0001) Korean Unexamined Patent Publication No. 10-1997-0058401 (published on Jul. 31, 1997)
(Patent Literature 0001) Korean Unexamined Utility Model Publication No. 20-1999-0030947 (published on Jul. 26, 1999)

### DETAILED DESCRIPTION OF THE INVENTION

### Technical Problem

The present invention has been designed to solve the problems of the prior art techniques, and therefore an object thereof is to provide a structure and method for failure diagnosis of a PCB board for article transport elevator in which lamps are mutually connected to circuit units of the PCB board connected to each functional unit of the elevator, and by using a lamp that performs turn-on/off operation in accordance with whether each functional unit operates normally or not, the presence or absence of a failure of each functional unit can be diagnosed collectively by looking at the PCB board, thereby offering excellent convenience for failure diagnosis.

### Technical Solution

According to the present invention, there is provided a structure and method for failure diagnosis of a PCB board for an article transport elevator, which allows a transport car loaded with articles to ascend/descend and arrive to a locker position selected from among lockers provided on each layer of a multi-layer structure, and allows the articles to be supplied by the door opening/closing operation of the locker where the transport car has arrived, wherein the PCB board is configured such that respective circuit units, which connect a power supply unit of an article transport elevator, a seesaw switch unit of each layer, a car arrival limit unit, a car operation condition unit and a car operation state unit through a connector; and lamps, which turn on in accordance with whether the power supply unit, the seesaw switch unit of each layer, the car arrival limit unit, the car operation condition unit and the car operation state unit operate normally or not, are installed so as to be connected to each other, thereby diagnosing the presence or absence of a failure of the power supply unit, the seesaw switch unit of each layer, the car arrival limit unit, the car operation condition unit and the car operation state unit depending on the presence or absence of turn-on/off operation of the lamps.

According to the present invention, the car operation condition unit is configured such that the lamps perform turn-on/off operation during use due to the lamp turn-on/off in any one or more of: during operation of the emergency limit installed on the uppermost and lowermost layers, during opening of the door limit installed on each layer between the uppermost and lowermost layers, and during overload of the emergency limit, the door limit and the driving motor.

According to the present invention, the car operation state unit is configured such that a buzzer that notifies and operates for a certain period of time if the transport car arrives at the locker of the selected layer; and the lamps perform turn-on/off operation during operation of ascent/descent arrows of each layer that operate during ascending and descending operation of the transport car.

According to the present invention, the connector of the PCB board is configured such that a connection terminal is installed on the inner side of an insertion groove into which a wire of each functional unit is horizontally inserted, and a clamping bolt that clamps the wire of each functional unit inserted into the connection terminal is screw-connected to the vertical upper portion of the connection terminal.

### Advantageous Effects

An article transport elevator of the present invention may connect the lamps that turn on in accordance with whether each functional unit operates normally or not to the circuit unit of the PC board connected to each functional unit such as the power supply unit, the seesaw switch unit of each layer, the car arrival limit unit, the car operation condition unit, and the car operation state unit, thereby looking at the circuit unit of the PC board and collectively diagnosing the presence or absence of a failure of the power supply unit, the seesaw switch unit of each layer, the car arrival limit unit, the car operation condition unit and the car operation state unit in a simple and quick manner in accordance with the presence or absence of turn-on/off operation of the lamps.

### BRIEF DESCRIPTION OF THE DRAWINGS

FIG. 1 is a perspective photograph of a switch board in which a PCB board of the present invention is installed.

FIG. 2 is a perspective photograph illustrating the PCB board of FIG. 1.

FIG. 3 is a plan view illustrating the principal parts of an example of a PCB board (for 3 layers) to which the present invention is applied.

FIG. 4 is a plan view illustrating the principal parts of a circuit unit and a lamp of FIG. 3.

FIG. 5 is a plan view illustrating the principal parts of another example of a PCB board (for 2 layers) to which the present invention is applied.

FIG. 6 is a plan view illustrating the principal parts of a circuit unit and a lamp of FIG. 5.

FIG. 7 is a cross-sectional configuration diagram illustrating the structure before and after connecting wires to the connector of the present invention.

FIG. 8 is a plan view illustrating the user manual of FIG. 5.

### DETAILED DESCRIPTION OF THE EMBODIMENTS

First, a structure for failure diagnosis of a PCB board for article transport elevator according to the present invention will be described with reference to the accompanying drawings.

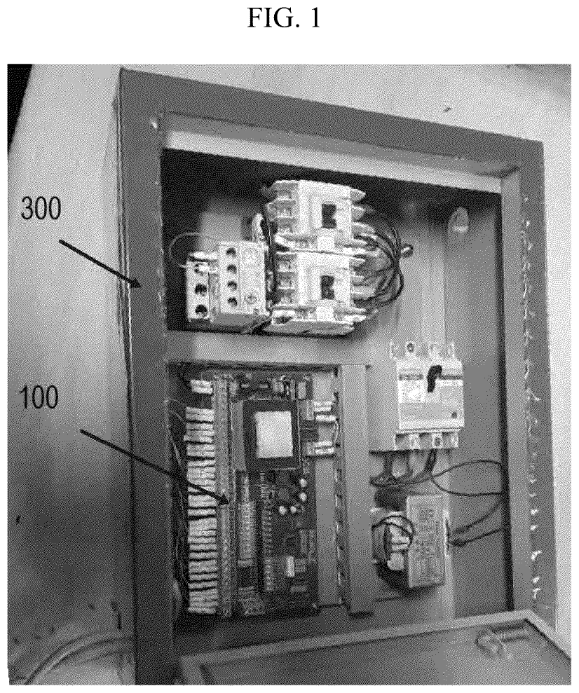

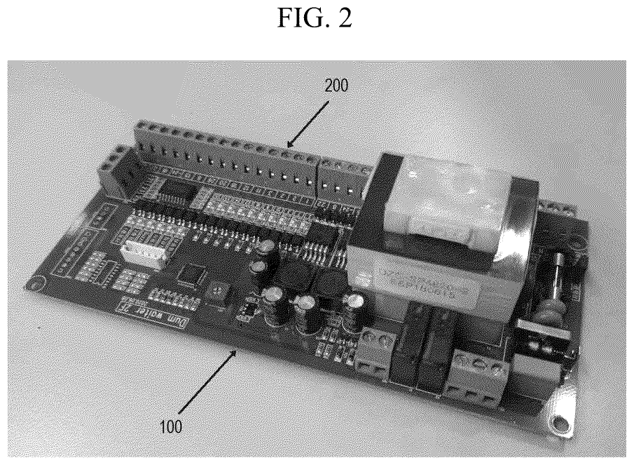

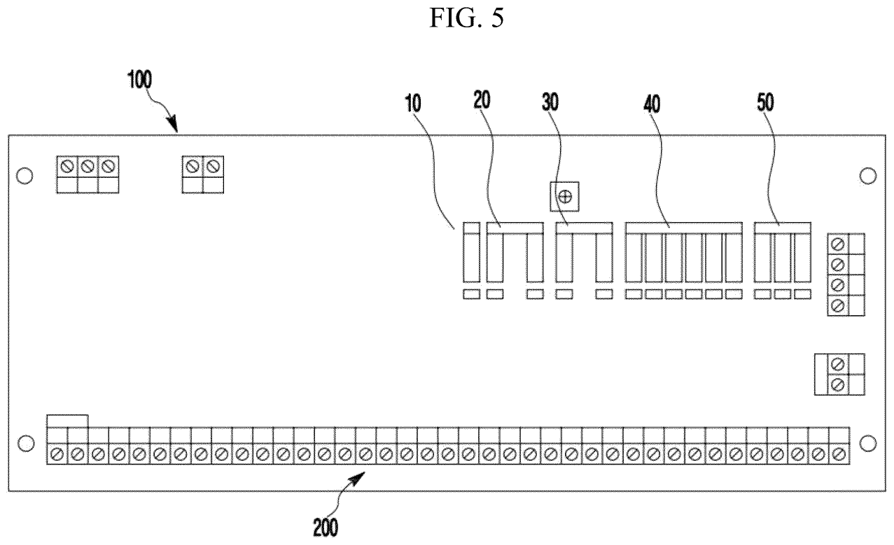

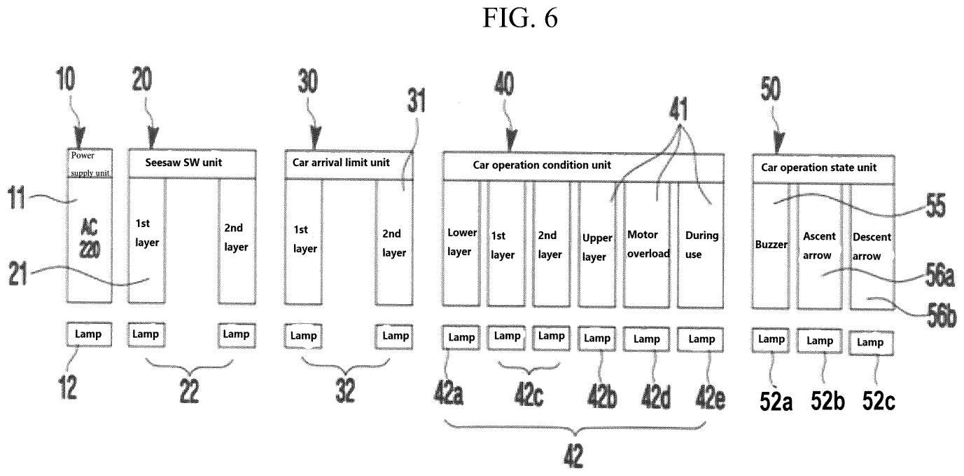

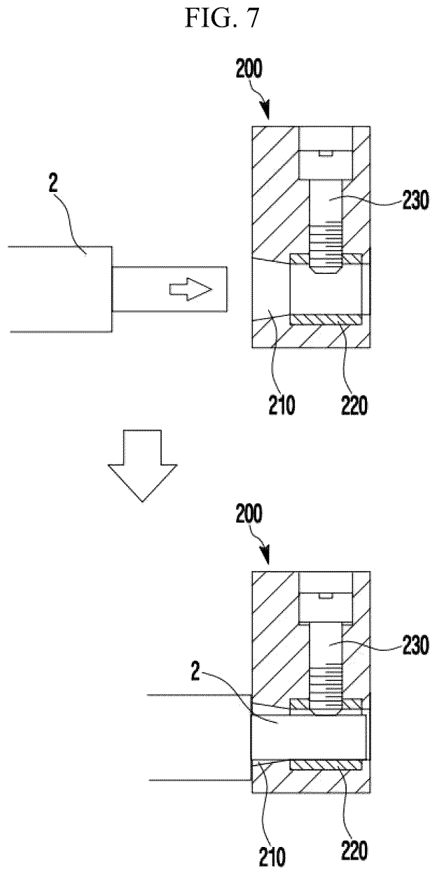

The present invention provides a structure for failure diagnosis of a PCB board 100 for an article transport elevator, which allows a transport car loaded with articles to ascend/descend and arrive to a locker position selected from among lockers provided on each layer of a multi-layer structure, and allows the articles to be supplied by the door opening/closing operation of the locker where the transport car has arrived, as illustrated in FIGS. 1 to 8.

That is, the PCB board 100 of the present invention is configured such that respective circuit units 11, 21, 31, 41 and 51, which connect a power supply unit 10 for supplying power to an article transport elevator, a seesaw switch unit 20 installed on the surface panel of each layer, a car arrival limit unit 30 installed on each layer to detect the arrival of a transport car, a car operation condition unit 40 and a car operation state unit 50 through a connector 200; and lamps 12, 22, 32, 42 and 52, which turn on in accordance with whether the power supply unit, the seesaw switch unit of each layer, the car arrival limit unit, the car operation condition unit and the car operation state unit operate normally or not, are installed so as to be connected to each other, thereby diagnosing the presence or absence of a failure of the power supply unit, the seesaw switch unit of each layer, the car arrival limit unit, the car operation condition unit and the car operation state unit in accordance with the presence or absence of turn-on/off operation of the lamps 12, 22, 32, 42 and 52.

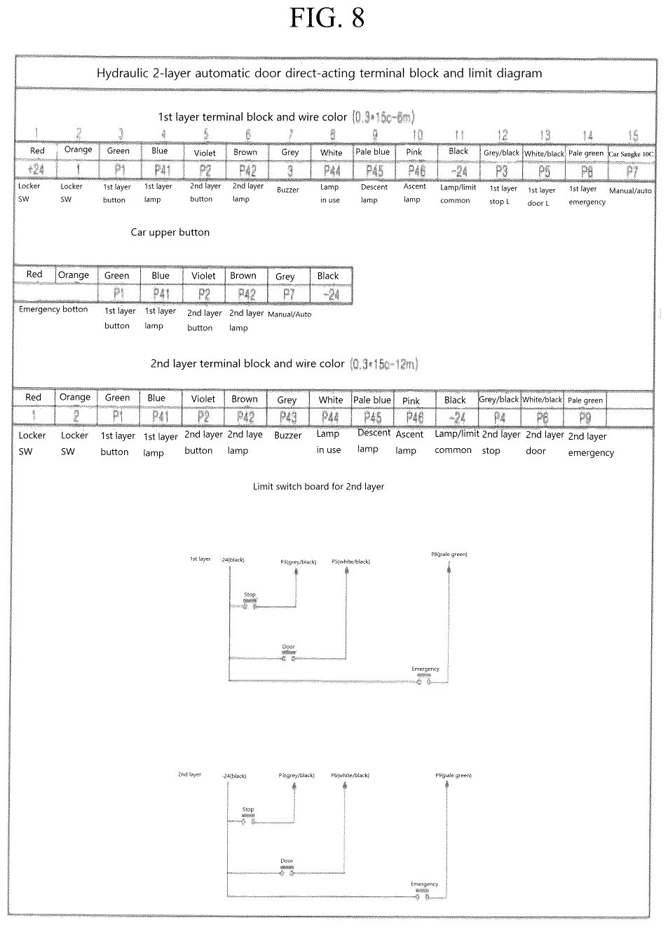

That is, an operator checks that the lamps 12, 22, 32, 42 and 52 of the PCB board 100 installed in the switch board perform turn-on/off operation, whereby even an unskilled person can collectively diagnose whether the power supply unit 10 of an article transport elevator, the seesaw switch unit 20 of each layer, the car arrival limit unit 30, the car operation condition unit 40, and the car operation state unit 50 operate normally or not, by looking at the user manual of FIG. 8.

Here, the power supply unit 10 is configured such that the lamp 12 performs a turn-on operation when power is supplied, but when the lamp is turned off, it is necessary to check the input power supply and the fuse.

In addition, the seesaw switch unit 20 is configured such that the lamp 22 performs a turn-on operation when the seesaw switch installed on the surface panel of each layer is turned on, and the car arrival limit unit 30 is configured such that, when a transport car arrives at the selected layer, it detect the arrival and the lamp 32 performs a turn-on operation.

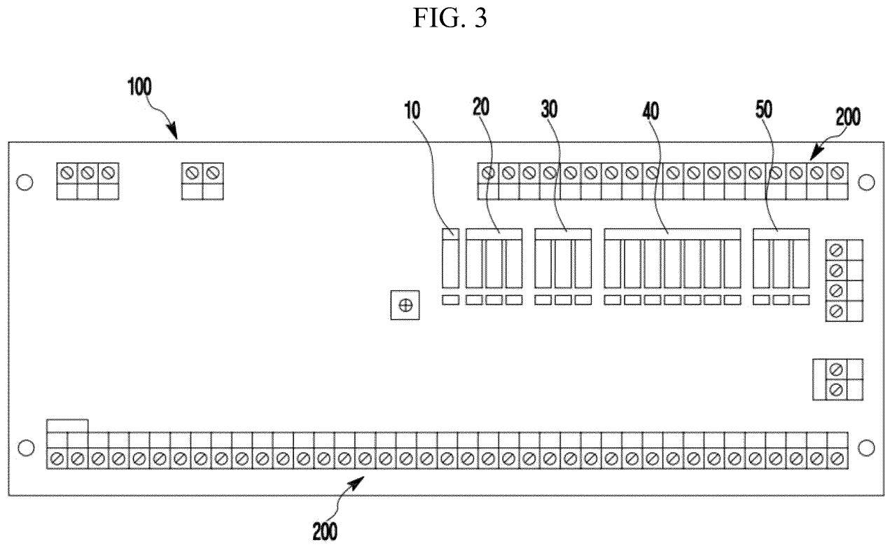

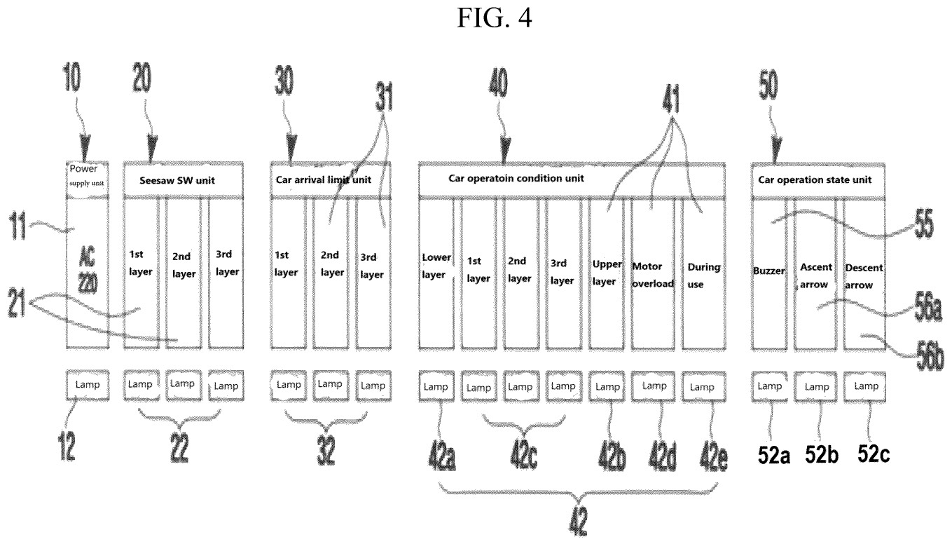

At this time, the seesaw switch unit 20 and the car arrival limit unit 30 are configured to be installed on the first, second and third layer layers in the case of a 3-layer structure as shown in FIG. 3, and installed on the first and second layers in the case of a 2-layer structure as shown in FIG. 4.

And, the car operation condition unit 40 is configured such that the lamps 42a, 42b, 42c, 42d and 42e connected to the respective functional parts perform turn-on/off operation during use due to the lamp turn-on/off in any one or more of: during operation of the emergency limit installed on the uppermost and lowermost layers and detecting the departure of the transport car, during opening of the door limit installed on each layer between the uppermost and lowermost layers, and during overload of the driving motor that drives the ascending and descending of the transport car.

At this time, the door limit is configured to connect the first, second and third layer door limits with the lamps of each door limit in the case of a 3-layer structure as shown in FIG. 3, and to connect the first and second layer door limits with the lamps of each door limit in the case of a 2-layer structure as shown in FIG. 4.

The car operation state unit 50 is configured such that a buzzer 55 that notifies and operates for a certain period of time if the transport car arrives at the locker of the selected layer, and the lamps 52a, 52b and 52c perform turn-on operation during operation of ascent/descent arrows 56a and 56b of each layer that performs turn-on operation during ascending and descending operation of the transport car.

In addition, the connector 200 of the PCB board is configured such that a connection terminal 220 is installed on the inner side of an insertion groove 210 into which a wire 2 of each functional unit is horizontally inserted, and a clamping bolt 230 that clamps the wire 2 of each functional unit inserted into the connection terminal is screw-connected to the vertical upper portion of the connection terminal, thereby be simply and firmly clamping the wire of each functional unit.

Reference numeral 300 (not shown) denotes a switch board.

Next, a method for failure diagnosis of a PCB board of the present invention configured as above will be described with reference to the attached drawings.

The article transport elevator of the present invention allows a transport car loaded with articles to ascend/descend and arrive to a locker position of the selected layer and then supplies the articles by the door opening/closing operation of the locker where the transport car has arrived, wherein when the transport car arrives at the selected layer, the buzzer lamp operates for a set time, an operator recognizes the arrival of the articles and receives supply of the articles by the door opening and closing operation.

According to the present invention, the PCB board 100 is installed inside the switch board 300, so that the operator can look and check the PCB board 100 of the switch board, wherein by checking the lamp turn-on/off operation of the PCB board connected to the power supply of the article transport elevator, the seesaw switch of each layer, the car arrival limit, the car operation condition unit and the car operation state unit, even a non-expert can collectively diagnose the operation in a simple and quick manner.

To explain this more specifically, the operator checks the turn-on/off operation of the lamp 12 of the PCB board in accordance to the operator manual of FIG. 8, and confirms and inspects whether the power supply unit 10 is powered and whether it is operated normally. At this time, if the lamp is turned-off, the input power and fuse failure are diagnosed.

And, by checking the turn-on/off operation of the lamp 22 of the PCB board, it is possible to confirm and inspect whether the seesaw switch 20 installed on the switch board of each layer is operated normally.

In addition, by checking the turn-on/off operation of the lamp 32 of the PCB board, it is possible to confirm and inspect whether the car arrival limit unit 30 that detects the arrival of the transport car on the selected layer is operated normally.

At this time, if the lamp 32 does not turn on, it can be confirmed that the car arrival limit unit 30 is broken or not installed in a fixed position, comes off from the installed position and is not operated normally. Therefore, it is possible to check and repair the car arrival limit.

In addition, by checking the turn-on/off operation of the lamps 42a, 42b, 42c, 42d and 42e of the PCB board, it is possible to confirm and inspect the operation of the emergency limit installed on the uppermost and lowermost layers, the open operation of the door limit installed on each layer between the uppermost and lowermost layers, and the overload of the driving motor that drives the ascending and descending of the car. Furthermore, it is possible to confirm and inspect whether the function during use operates normally or not by the lamp turn-on/off in any one or more of: the emergency limit, door limit, and driving motor overload.

At this time, the emergency limits of the uppermost and lowermost layers are normal B contacts and the lamps turn on when activated, the door limit is a normal A contact and the lamp turns on when opened, the motor overload is a normal B contact and the lamp turns on when overloaded, and the lamp in use turns on together when even any one of the emergency limit, the door limit, and the motor overload lamps turn on.

In addition, by checking the turn-on/off operation of the lamps 52a, 52b and 52c of the PCB board, it is possible to check and inspect whether the buzzer 55 that notifies and operates for a certain period of time if the transport car arrives at the locker of the selected layer, and the ascent/descent arrows 56a and 56b of each layer that performs turn-on operation during ascending and descending operation of the transport car are operated normally or not.

Therefore, the present invention checks the lighting status of the lamp mounted on the PCB board 100 of the switch board, and thereby enables even a non-expert to easily and quickly diagnose and take measures all at once to determine whether each functional unit of the elevator is operated normally or not, that is, whether each functional unit has caused a failure or not.

On the other hand, the PCB board 100 of the present invention can be mainly used for diagnosing a failure during the operation of an article transport elevator, and also can check the turn-on/off operation of the lamps of the PCB board even during the installation and construction of the article transport elevator, thereby checking whether the normal installation of the power supply unit 10, the seesaw switch unit 20 of each floor, the car arrival limit unit 30, the car operation condition unit 40, and the car operation state unit 50 has been completed, and making the initial installation setting easier and faster.

### DESCRIPTION OF REFERENCE NUMERALS

11, 21, 31, 41, 51: circuit unit
12, 22, 32, 42, 52: lamp
20: seesaw switch unit
30: car arrival limit unit
40: car driving condition part
50; car driving situation part
55: buzzer
56a,56b: ascent/descent arrows
100: PCB board
200: connector
210: insertion groove
220: connection terminal
230: clamping bolt

1. A structure for failure diagnosis of a PCB board for an article transport elevator, which allows a transport car loaded with articles to ascend/descend and arrive to a locker position selected from among lockers provided on each layer of a multi-layer structure, and allows the articles to be supplied by the door opening/closing operation of the locker where the transport car has arrived,
wherein the PCB board is configured such that respective circuit units, which connect a power supply unit of an article transport elevator, a seesaw switch unit of each layer, a car arrival limit unit, a car operation condition unit and a car operation state unit through a connector; and
lamps which turn on in accordance with whether the power supply unit, the seesaw switch unit of each layer, the car arrival limit unit, the car operation condition unit and the car operation state unit operate normally or not, are installed so as to be connected to each other, thereby diagnosing the presence or absence of a failure of the power supply unit, the seesaw switch unit of each layer, the car arrival limit unit, the car operation condition unit and the car operation state unit in accordance with the presence or absence of turn-on/off operation of the lamps.

2. The structure for failure diagnosis of a PCB board for an article transport elevator according to claim 1, wherein:
the car operation condition unit is configured such that the lamps perform turn-on/off operation during use due to the lamp turn-on/off in any one or more of: during operation of the emergency limit installed on the uppermost and lowermost layers, during opening of the door limit installed on each layer between the uppermost and lowermost layers, and during overload of the emergency limit, the door limit and the driving motor.

3. The structure for failure diagnosis of a PCB board for an article transport elevator according to claim 1, wherein:
the car operation state unit is configured such that a buzzer that notifies and operates for a certain period of time if the transport car arrives at the locker of the selected layer; and the lamps perform turn-on/off operation during operation of ascent/descent arrows of each layer that operate during ascending and descending operation of the transport car.

4. The structure for failure diagnosis of a PCB board for an article transport elevator according to claim 1, wherein:
the connector of the PCB board is configured such that a connection terminal is installed on the inner side of an insertion groove into which a wire of each functional unit is horizontally inserted, and a clamping bolt that clamps the wire of each functional unit inserted into the connection terminal is screw-connected to the vertical upper portion of the connection terminal.

5. A method for failure diagnosis of a PCB board for an article transport elevator, characterized in that in the PCB board for an article transport elevator which allows a transport car loaded with articles to ascend/descend and arrive to a locker position selected from among lockers provided on each layer of a multi-layer structure, and allows the articles to be supplied by the door opening/closing operation of the locker where the transport car has arrived, respective circuit units that connect a power supply unit of an article transport elevator, a seesaw switch unit of each layer, a car arrival limit unit, a car operation condition unit, and a car operation state unit through a connector; and lamps that turn on in accordance with whether the power supply unit, the seesaw switch unit of each layer, the car arrival limit unit, the car operation condition unit, and the car operation state unit operate normally or not, are installed so as to be connected to each other,
whereby an operator collectively diagnoses the presence or absence of a failure of the power supply unit, the seesaw switch unit of each layer, the car arrival limit unit, the car operation condition unit, and the car operation state unit in accordance with the presence or absence of turn-on/off operation of the lamps of the PCB board.
